(19) United States
(12) Patent Application Publication
(10) Pub. No.: US 2007/0042611 A1
(43) Pub. Date: Feb. 22, 2007

(54) Method of producing a trench in a photo-resist on a III-V wafer and a compound wafer having a photo-resist including such a trench

(76) Inventor: Jason McMonagle, Darlington (GB)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(21) Appl. No.: 11/506,304

(22) Filed: Aug. 18, 2006

(30) Foreign Application Priority Data
Aug. 18, 2005 (GB) 0516932.1

(51) Int. Cl. H01L 21/31; H01L 21/469

(52) U.S. Cl. 438/780; 257/E21.261

(57) ABSTRACT

A method of producing a trench in a photo-resist on a III-V wafer comprising providing a III-V wafer; providing a photo-resist on the wafer; exposing the photo-resist to UV radiation through a mask; removing one of the exposed or non-exposed portions of the photo-resist to produce a recess; applying a polymer spacer to the photo-resist; heating the wafer to initiate a polymer cross linking reaction at the interface of the photo-resist and polymer; and removing the un-reacted polymer.

The present invention relates to a method of producing a trench in a photo-resist on a III-V wafer. The present invention also relates to a compound wafer having a photo-resist including such a trench.

It is often desired to produced narrow trenches in photo-resists on III-V wafers. The narrow trench width reduces the size of the gate which can deposited on the wafer which in turn improves the high frequency performance of transistors manufactured from the wafer.

Narrow trenches in photo-resists can be generated by a narrow electron beam. The beam must write the trench pattern on the wafer. For a large wafer it can take several hours to produce the required pattern.

An alternative is to illuminate the photo-resist with a mid-UV or deep UV radiation through gaps in a mask. Large areas can simultaneously be illuminated which reduces the processing time. However, the dimensions of the trenches formed are diffraction limited to the same order of magnitude as the wavelength of the light. For illumination sources typically used (such as a Hg lamp or a KrF excimer laser)the resulting trenches are too large (of the order 250 nm) reducing the resulting transistor performance.

Accordingly, the present invention provides a method of producing a trench in a photo-resist on a Ill-V wafer comprising
providing a III-V wafer;
providing a photo-resist on the wafer;
exposing the photo-resist to UV radiation through a mask;
removing one of the exposed or the non exposed portions of the photo-resist to produce a recess;
applying a polymer spacer to the photo-resist;
heating the wafer to initiate a polymer cross linking reaction at the interface of the photo-resist and polymer; and
removing the un-reacted polymer.

The method according to the invention allows processing by a step is and repeat photolithography process, reducing processing time. The resulting trench width however is less than that of the wavelength of the UV light used, improving transistor performance.

The exposed portion of the photoresist can be removed to form the recess. Alternatively the non exposed parts of the photoresist can be removed to form the recess.

Preferably, the polymer spacer is applied as an aqueous solution.

The polymer spacer can be spin coated onto the wafer.

The heating step can comprise an initial soft bake to remove excess moisture and followed by a second higher temperature bake, preferably a hot plate bake to initiate the cross linking reaction.

The method can further comprise the step of cooling the wafer after heating to halt the reaction.

The un-reacted polymer can be removed by rinsing, preferably with de-ionised water.

The method can comprise a further baking step after removal of the un-reacted polymer to remove excess water.

The method can further comprise the step of cooling the substrate after the further baking step.

The polymer spacer can be polyvinyl acetate.

The III-V wafer can comprise a GaAs layer. Preferably, the GaAs wafer further comprises at least one layer of at least one of AlGaAs and InGaAs.

The III-V wafer can comprise an InP layer.

The III-V wafer can comprise a 2DEG layer separated from the upper surface of the wafer by a Schotkky barrier.

Preferably, exposure to the UV reaction is done by step and repeat photolithography.

In a further embodiment of the invention there is provided a compound wafer comprising
a III-V wafer; and
a photo-resist layer on said III-V wafer, the photo-resist layer including a trench extending down to the wafer, the photo-resist layer being coated with a cross linked polymer.

The III-V wafer can comprise a GaAs layer.

The III-V wafer can further comprise at least one layer of at least one of AlGaAs and InGaAs.

The III-V wafer can further comprise a layer of InP.

The III-V wafer can comprise a 2DEG layer separated from the upper surface of the wafer by a Schottky layer.

The polymer can be polyvinyl acetate.

The present invention will now be described by way of example only and not in any limitative sense with reference to the accompanying drawings in which

FIGS. 1 to 7 show, in schematic form, a process flow of the method according to the invention, using a III-V wafer;

and FIG. 8 shows a further III-V wafer according to the invention including the photo-resist layer.

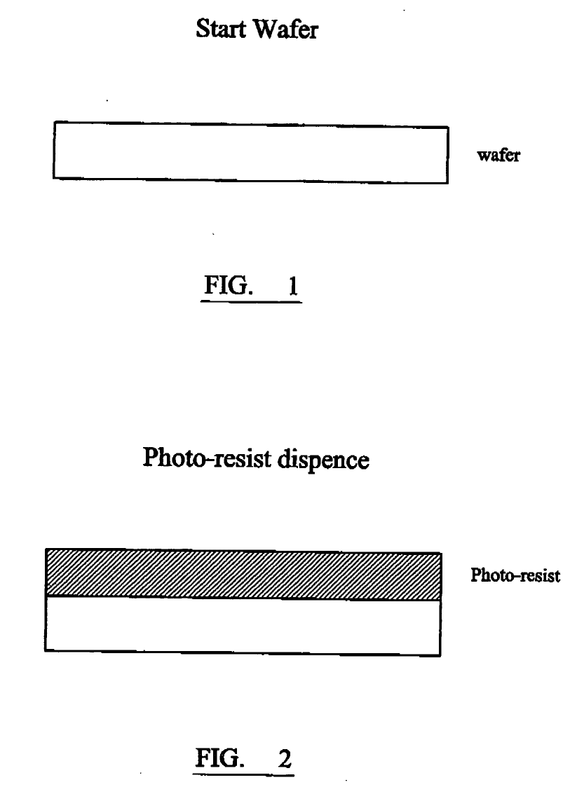

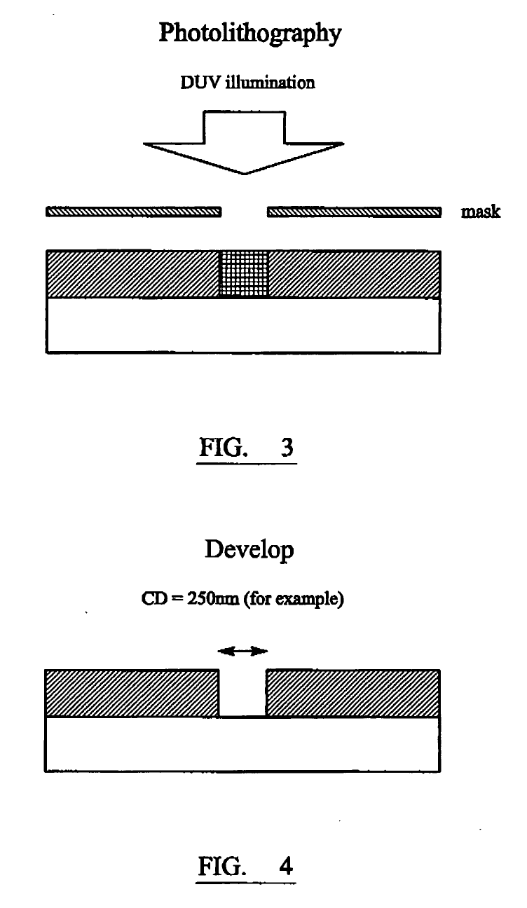

Firstly, a III-V wafer, (in this case a GaAs wafer) is provided (FIG. 1). A photo-resist (for example, Shipley UV210)is laid down in a layer on the wafer by known methods and stabilised by a stabilisation bake (FIG. 2). This is then optically exposed through a mask using deep ultraviolet radiation, for example a KrF excimer laser (FIG. 3). Following exposure the wafer is again baked and the pattern is then developed (for example with Shipley LDD 26W) to remove the exposed area of the photo-resist, leaving a trench extending through the photo-resist to the wafer (FIG. 4).

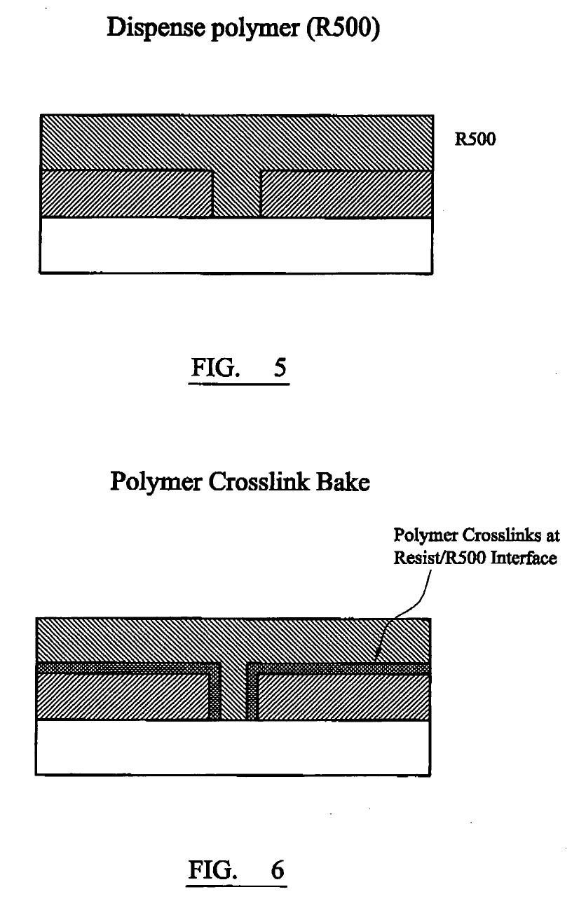

A polymer spacer (for example AZ Materials R500) is applied to the patterned wafer as an aqueous solution. This is spin coated at around 2000-4000 rpm to achieve uniform coating of the order 3000-4000 Å (shown in FIG. 5). The wafer is then processed through a hot plate soft bake at around 85° c to remove excess solvent and moisture from the polymer film. This is followed by subsequent high temperature hot plate bake at between 105° c and 130° c in order to initiate a polymer cross linking reaction at the interface of the photo-resist and the AZR 500 (FIG. 6). The wafer is then transferred to a cool plate at around 23° c to halt the reaction.

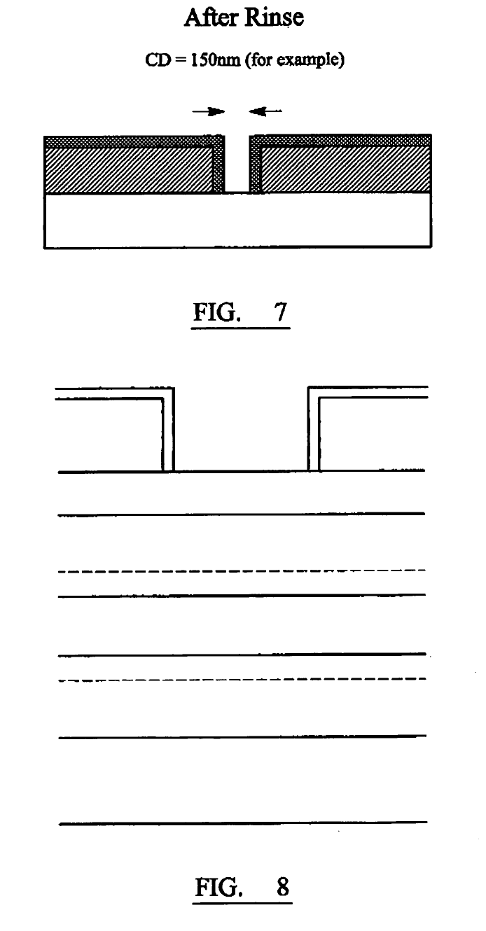

The wafer is rinsed with de-ionised water as shown in FIG. 7 to remove the un-reacted R500 material from the wafer surface. After the rinse the wafer is baked at around 110° c to remove any remaining water and is finally cooled to ambient conditions on a temperature controlled cooled plate at around 23° c. Whilst the unreacted polymer spacer is removed, the reacted cross linked polymer remains so reducing the trench width as shown.

The method according to the invention has been shown with reference to a simple GaAs wafer. It is often desirable to produce trenches is more complex water structures. Shown in FIG. 8 is a more complex wafer structure suitable for use in the manufacture of a pHEMT FET. The wafer comprises a GaAs substrate. On the GaAs substrate is an AlGaAs buffer layer. On top of the buffer layer is a semiconductor channel layer. The semiconductor channel layer comprises a InGaAs electrically conducting channel. On each side of the electrically conducting channel is a supply layer of silicon atoms. The supply layers of silicon atoms are spaced from the electrically conducting channel by AlGaAs spacer layers. The supply layer of silicon atoms supply electrons to the electrically conducting channel forming a high mobility two dimensional electron gas (2DEG). On top of the top Si supply layer is an AlGaAs Schottky layer and forming the upper surface of the semiconductor channel layer is a GaAs coating. On top of the wafer is the photo-resist including the recess extending down to the wafer. The photo-resist is coated with the cross linked polymer coating, reducing the recess width.

The method according to the invention is suitable for use with other compound wafers for example wafer suitable for manufacture of HEMT FETS.

In an alternative embodiment of the invention (not shown) the wafer comprises an InP substrate. The wafer further comprises a spacer between the InP layer and the remainder of the wafer.

In a further embodiment of the invention (not shown), the illumination is provided by a mercury lamp.

1. A method of producing a trench in a photo-resist on a Ill-V wafer comprising:
providing a III-V wafer;
providing a photo-resist on the wafer;
exposing the photo-resist to UV radiation through a mask;
removing one of the exposed or non-exposed portions of the photo-resist to produce a recess;
applying a polymer spacer to the photo-resist;
heating the wafer to initiate a polymer cross linking reaction at the interface of the photo-resist and polymer; and
removing the un-reacted polymer.

2. A method as claimed in claim 1, wherein the exposed portion of the photo-resist is removed to form the recess.

3. A method as claimed in claim 1, wherein the non-exposed portion of the photo-resist is removed to form the recess.

4. A method as claimed in claim 1, wherein the polymer spacer is applied as an aqueous solution.

5. A method as claimed in claim 4, wherein the polymer spacer is spin coated onto the wafer.

6. A method as claimed in claim 1, wherein the heating step comprises an initial soft bake to remove excess moisture followed by a second higher temperature bake, preferably a hot plate bake to initiate the cross linking reaction.

7. A method as claimed in claim 6, further comprising the step of cooling the wafer after baking to halt the reaction.

8. A method as claimed in claim 1, wherein the un-reacted polymer is removed by rinsing, preferably with deionised water.

9. A method as claimed in claim 1, further comprising a further baking step after removal of the un-reacted polymer to remove excess water.

10. A method as claimed in claim 9, further comprising the step of cooling the substrate after the further baking step.

11. A method as claimed in claim 1, wherein the polymer spacer is polyvinyl acetate.

12. A method as claimed in claim 1, wherein the III-V wafer comprises a GaAs layer.

13. A method as claimed in claim 12, wherein the GaAs wafer further comprises at least one layer of at least one of AlGaAs and InGaAs.

14. A method as claimed in claim 1, wherein the Ill-V wafer comprises an InP layer.

15. A method as claimed in claim 12, wherein the III-V wafer comprises a 2DEG layer separated from the upper surface of the wafer by a Schotkky barrier.

16. A method as claimed in claim 1, whereby exposure to the UV reaction is done by step and repeat photolithography.

17. A compound wafer comprising:
a III-V wafer; and
a photo-resist layer on said Ill-V wafer, the photo-resist layer including a trench extending down to the wafer, the photo-resist layer having a coating of a cross linked polymer thereon.

18. A compound wafer as claimed in claim 17, wherein the III-V wafer comprises a GaAs layer.

19. A compound wafer as claimed in claim 18, further comprising at least one layer of at least one of AlGaAs and InGaAs.

20. A compound wafer as claimed in claim 17, further comprising a layer of InP.

21. A compound wafer as claimed in claim 17, wherein the III-V wafer comprises a 2DEG layer separated from the upper surface of the wafer by a Schottky layer.

22. A compound wafer as claimed in claim 17, wherein the polymer is polyvinyl acetate.
